(19) United States
(12) Patent Application Publication
(10) Pub. No.: US 2026/0333707 A1
(43) Pub. Date: Oct. 22, 2026

(54) MEMORY DEVICE AND A METHOD FOR MANUFACTURING A MEMORY DEVICE

(71) Applicant: IMEC VZW, Leuven (BE)

(72) Inventors: Anastasiia Kruv, Pelenberg (BE); Geert Hellings, Halle (BE); Mario Gonzalez, Bossut-Gottechain (BE)

(21) Appl. No.: 19/653,714

(22) Filed: Apr. 21, 2026

(30) Foreign Application Priority Data
Apr. 22, 2025 (EP) 25171614.8

(51) Int. Cl. H10B 53/30; H10B 12/00; H10B 53/10; H10B 53/20; H10D 1/68

(52) U.S. Cl. CPC H10B 53/30; H10B 12/03; H10B 12/482; H10B 12/488; H10B 53/10; H10B 53/20; H10D 1/684; H10D 1/692; H10D 1/716

(57) ABSTRACT

A memory device is provided. The memory device includes a plurality of conductive lines and a plurality of isolating layers alternately stacked in a vertical direction. The memory device further includes a hole extending through the conductive lines and isolating layers, with the hole extending in the vertical direction. The memory device also includes an electrode extending through the hole in the vertical direction and a stressor extending through the hole in the vertical direction. For each conductive line, a dielectric layer including a ferroelectric layer is arranged on an inner surface of the hole through the conductive line. The electrode and the stressor are arranged on an inner side of the dielectric layer. The stressor applies a strain to the ferroelectric layer of the dielectric layer.

### CROSS-REFERENCE TO RELATED APPLICATION(S)

The present application is a non-provisional patent application claiming priority to European Patent Application No. EP 25171614.8, filed Apr. 22, 2025, the contents of which are hereby incorporated by reference.

### FIELD OF THE DISCLOSURE

The present disclosure relates to a memory device.

### BACKGROUND

A dynamic random-access memory (DRAM) is a memory device including a capacitor that stores charge. The charge presence and absence may be coded as logical “1” or “0”, respectively. As time progresses, the capacitor loses the charge that it is supposed to store, which may (e.g., eventually) lead to information loss. To prevent or minimize information loss, the DRAM may be refreshed.

A ferroelectric DRAM is a DRAM wherein the capacitor’s dielectric includes ferroelectric material. A ferroelectric material is a material that has two stable non-volatile polarization states and may switch between the two states under the electric field application. The use of ferroelectric material may reduce or eliminate memory refresh.

### SUMMARY

The present disclosure provides a memory device which is useful (e.g., reliable). The present disclosure further provides a memory device with long storage time. A memory device which is compact is further provided. A memory device which is easy to manufacture and/or inexpensive is further provided.

For example, conventional ferroelectric memory devices may be improved. As such, a ferroelectric memory device which, for example, is reliable, has a long storage time, is compact, easy to manufacture, and/or is inexpensive is provided herein.

These and other improvements of the present disclosure are at least partly provided herein and by the independent claims. Example embodiments are set out in the independent and/or dependent claims.

In the following, relative spatial terms such as “top,” “bottom,” “lower,” “vertical,” “stacked on top of,” may denote locations or directions within a frame of reference of the memory device. For example, the terms may be in relation to a normal direction to a substrate on which the memory device is arranged. Correspondingly, terms such as “lateral” and “horizontal” may be locations or directions parallel to the substrate.

A vertical direction may be the normal direction to the substrate. A first and a second horizontal direction may respectively be directions parallel to the substrate.

According to a first example embodiment, a memory device is provided. The memory device includes a plurality of conductive lines and a plurality of isolating layers, alternately stacked in a vertical direction. The memory device includes a hole extending through the conductive lines and the isolating layers, with the hole extending in the vertical direction. The memory device includes an electrode extending through the hole in the vertical direction, and a stressor extending through the hole in the vertical direction. For each conductive line, a dielectric layer including a ferroelectric layer is arranged on an inner surface of the hole through the conductive line. The electrode and the stressor are arranged on an inner side of the dielectric layer. The stressor applies a strain to the ferroelectric layer of the dielectric layer.

Applying strain to the ferroelectric layer by a stressor may improve the memory device. The ferroelectric layer is a layer including ferroelectric material. Ferroelectric material has two polarization states (e.g., +Pr and -Pr). The higher the magnitude of polarization, the easier it may be to distinguish the +Pr and -Pr states from each other. The memory window (e.g., 2Pr) between the two states may increase, facilitating a reliable memory device. For example, a memory device with a reliable read operation (e.g., the states are easily distinguishable) may be facilitated. In such scenarios, the storage time may be long since a large memory window may provide margin for a partial de-polarization before the memory device is (e.g., needs to be) refreshed. Here, eliminating refresh may be possible.

In accordance with the above, the memory device may be a ferroelectric memory device.

Further, the memory device may be a memory device of a 1TnC (one transistor, number (n) capacitors) type, providing that the device may include at least one transistor (e.g., one select transistor) per number (n) of capacitors.

The plurality of conductive lines stacked in the vertical direction may be referred to as a stack of conductive lines. The conductive lines may extend in a first horizontal direction.

In the present disclosure, a conductive line is a line including conductive material, e.g., metal (such as tungsten, molybdenum, ruthenium, copper, or titanium), doped polysilicon, or titanium nitride. The conductive lines may be word lines. Alternatively, the conductive lines may be plate lines.

The conductive lines and the isolating layers are alternately stacked. Thus, within the stack of conductive lines, neighboring conductive lines are separated by an isolating layer. The isolating layers may include an electrically isolating material, e.g., oxide. For example, the isolating layers may include silicon oxide.

There may be a plurality of holes extending through the stack of conductive lines. The plurality of holes may be spaced apart (e.g., along the extension of the conductive line) by a first pitch in the first horizontal direction. Further, the memory device may include a plurality of stacks of conductive lines, e.g., the same or similar (e.g., identical) stacks of conductive lines. The plurality of stacks of conductive lines may be spaced apart by a second pitch in a second horizontal direction. The second horizontal direction may be perpendicular to the first horizontal direction. Adjacent stacks of conductive lines may be separated by an electrically isolating material, e.g., the same electrically isolating material as the isolating layers.

For each conductive line, the conductive line, the dielectric layer, and the electrode may form a capacitor. Thus, a number (n) of capacitors may be stacked on top of each other. The number (n) of stacked capacitors may be equal to the number of stacked conductive lines. Each capacitor may include a ferroelectric layer. Accordingly, the memory device may include a plurality of stacks of capacitors, spaced apart by the first pitch in the first horizontal direction and spaced apart by the second pitch in the second horizontal direction. For example, the capacitors may be arranged in a three-dimensional (3D) matrix. Such a memory device may be referred to as a 3D memory device.

The memory device may further include a bit line and a select transistor, wherein the electrode is connected to the bit line via the select transistor. Thus, there may be (e.g., at least) one select transistor per stack of number (n) capacitors, e.g., the memory device may be a 1TnC memory device. The select transistor may be arranged at the bottom or top of the hole. Thus, the select transistor may be arranged below or above the plurality of conductive lines.

For example, a (e.g., one) single stack of capacitors, i.e., one single stack of conductive lines and one single hole through the stack of conductive lines, is provided. The discussion and examples applicable to a single stack of capacitors may be applicable to all stacks of capacitors of the memory device.

The hole may be arranged such that, in a horizontal plane intersecting at least one of the conductive lines, the (e.g., entire) perimeter of the hole is in contact with the conductive line. Thus, the hole may be surrounded by the conductive line in the horizontal plane. A large hole area in contact with the conductive line may be provided, which in turn may facilitate a large capacitance. Alternatively, the hole may be arranged such that, in the horizontal plane intersecting at least one of the conductive lines, part of the perimeter of the hole is in contact with the conductive line, e.g., at least 1/4 or 1/2 of the perimeter is in contact with the conductive line. In the latter alternative, the other part of the perimeter of the hole may be in contact with the dielectric material separating the stacks of conductive lines.

The electrode extends through the hole in the vertical direction. Thus, the electrode may be a common electrode of the capacitors in the stack of capacitors. Accordingly, the inner side of the capacitors in the stack of capacitors may be directly connected to each other, e.g., without any intermediate transistors. The electrode may include electrically conductive material, e.g., metal (such as tungsten, molybdenum, ruthenium, copper, or titanium), doped polysilicon, or titanium nitride.

The electrode may be in direct contact with an inner surface of the dielectric layer. Thus, the stressor may be arranged on an inner side of the electrode, e.g., on an inner surface of the electrode. Alternatively, the stressor may be arranged between the electrode and the dielectric layer.

The dielectric layer may (e.g., solely) include the ferroelectric layer. Alternatively, the dielectric layer may include further layers. For example, the dielectric layer may include a first dielectric sublayer between the ferroelectric layer and the conductive line. Additionally, or alternatively, the dielectric layer may include a second dielectric sublayer between the ferroelectric layer and the electrode. The dielectric layer may be a tubular layer, i.e., a layer having a tubular shape.

A (e.g., one) single ferroelectric layer may extend through the (e.g., entire) hole in the vertical direction. Thus, each respective ferroelectric layer in the hole of each respective conductive line may be a respective portion of the same ferroelectric layer. As an alternative, each respective ferroelectric layer in the hole of each respective conductive line may be an individual layer. Accordingly, in the (e.g., latter) alternative, ferroelectric layers of the holes of neighboring conductive lines may be disconnected from each other.

The ferroelectric layer may include any ferroelectric material, including, for example, but not limited to, hafnium oxide, lead zirconate titanate, strontium bismuth tantalate, barium strontium titanate, and/or perovskite ferroelectrics. Such ferroelectric materials may facilitate a large memory window and a reliable memory device. The ferroelectric layer may include, for example, HfO₂, BaTiO₃, PbTiO₃, PbZrO₃, KNbO₃, LiNbO₃, LiTaO₃, SbSI, KTiOPO₄, KH₂PO₄, PbZrO₃, PbBi₂Nb₂O₉, SrBi₂Ta₂O₉, Ba_{0.73}Sr_{0.27}TiO₃, Bi₄Ti₃O₁₂, HfZrO₂, and/or ZrO₂. For example, the ferroelectric layer may include HfO₂.

The stressor may be any element applying strain to the ferroelectric layer. The stressor may induce stress (e.g., stress corresponding to force per unit area) to the ferroelectric layer, either directly or via an intermediate layer. The applied stress may then cause strain (e.g., a deformation) in the ferroelectric layer. The present disclosure relating to stress may be (e.g., equally) applicable to strain.

The applied strain may be measured in various ways, as provided below.

Strain may be measured by Raman Spectroscopy, e.g., by measuring the shift in Raman peaks caused by strain in a crystal lattice.

Strain may be measured by X-ray Diffraction (XRD). Herein, strain may be measured by analyzing the diffraction patterns of X-rays passing through the material.

Strain may be measured by Transmission Electron Microscopy (TEM). For example, a lamella may be extracted and measured by TEM. The thickness of the lamella may be chosen to be thick enough such that the strain is not fully relaxed by the extraction of the lamella.

Strain may be measured by Electron Backscatter Diffraction (EBSD).

Strain may be measured by nanoindentation. By pressing a hard tip into the surface of the material, the resulting deformation may be analyzed and the strain calculated. For example, force-displacement curves of the tip may be recorded. Then, with Finite Element Modelling, a model of the device may be created and force-displacement curves may be simulated. By changing the values of an initial strain state, it may be possible to fit the experimental and modelled curves, to determine the correct initial strain state.

Further, the strain may be calculated based on the electrical performance of the memory device. For example, the stressor may be removed (e.g., by etching) and the memory device may be electrically measured before and after the removal of the stressor. The stressor may be (e.g., fully) removed, and the device may be electrically measured before and after the removal. Alternatively, the stressor may be removed in incremental steps, and the device may be electrically measured between the steps. The strain may be calculated from the electrical measurements using, for example, Technology Computer-Aided Design (TCAD). Further, electrical measurements may be combined with nanoindentation to calculate the strain.

The stressor may be a layer on the inner side of the electrode. For example, the electrode is a layer, e.g., a tubular layer, on the inner side of the dielectric layer, and the stressor is a layer, e.g., a tubular layer, on the inner side of the electrode. Thus, the hole may not necessarily be (e.g., completely) filled. As such, the hole may be partially filled. Alternatively, the stressor may fill the inner side of the dielectric layer completely. Thus, the stressor may be a rod at the center of the hole.

The stressor may be a layer, e.g., a tubular layer, between the electrode and the dielectric layer.

Arranging the stressor in the hole facilitates (e.g., efficient) application of the strain to the ferroelectric layer. For example, relaxation of the stressor may be inhibited on the inner side of the stressor. Thus, the stress may be directed to elements on an outer side of the stressor, e.g., towards the ferroelectric layer.

The arrangement of the stressor may be useful for a stack of capacitors as described above, since the capacitors may be arranged closely (e.g., close to each other) and thereby (e.g., all) benefit from a common stressor. For example, the arrangement of the stressor may be useful for a 1TnC device. In a 1TnC device, there may be no transistor, between neighboring capacitors, that disturb the strain applied by the stressor.

The memory device may be configured such that, for each conductive line, a magnitude of the strain of the ferroelectric layer is at least 0.03%. The absolute value of the strain of the dielectric layer may be at least 0.03%. Such a magnitude may provide a (e.g., sufficient) increase of the memory window. Further improvements may be provided when the magnitude of the strain of the dielectric layer is at least 0.09% or at least 0.12%.

The memory device may be configured such that, for each conductive line, the strain of the ferroelectric layer is a compressive strain. Both tensile and compressive strains may be useful. Depending on the configuration of the memory device, the (e.g., most) useful type of strain may be either tensile or compressive strain. For example, depending on the material of the ferroelectric layer, the (e.g., most) useful type of strain may be either tensile or compressive strain. The strain type of the ferroelectric layer may be tensile strain. Alternatively, the strain type of the ferroelectric layer may be compressive strain. Compressive strain may be useful when the material of the ferroelectric layer is hafnium oxide.

The memory device may be configured such that, for each conductive line, the hole through the conductive line is (e.g., completely) filled by the dielectric layer, the electrode and the stressor. Such arrangement may (e.g., efficiently) direct the stress to elements on the outer side of the stressor, e.g., towards the ferroelectric layer. For example, the stressor may be prevented from relaxing towards an inner side when the hole is (e.g., completely) filled.

The memory device may be configured such that, for each conductive line, an area of the stressor is larger than an area of the dielectric layer, when viewed in a horizontal cross-sectional plane, facilitating a large strain in the ferroelectric layer and/or flexibility in the choice of materials for the stressor and the ferroelectric layer.

For each conductive line, an area of the stressor may be a factor of (e.g., about) 1.5 times larger than an area of the dielectric layer, when viewed in a horizontal cross-sectional plane.

Further, for each conductive line, an area of the stressor may be a factor of (e.g., about) 2 times larger than an area of the dielectric layer, when viewed in a horizontal cross-sectional plane.

The memory device may be configured such that the hole has a circular cross-section. A cross-section, which is circular by design, may be distorted by fabrication imperfections. A circular cross-section may thus be construed as circular within fabrication tolerances. A circular cross-section may facilitate homogeneous strain distribution in the ferroelectric layer. A circular cross-section may facilitate a high average strain in the ferroelectric layer. Thus, focusing the strain on smaller regions may be inhibited.

As an alternative to a circular cross-section, the cross-section may be oval.

As further alternatives, the cross-section may be square or rectangular.

The hole may not be a perfect cylinder. The hole may have the shape of a truncated cone. Thus, the area of the hole at the bottom may be smaller than at the top due to, for example, imperfect etching.

The memory device may be configured such that the electrode and the stressor include a same material. For example, a metal may act as both a stressor and an electrode.

In the case where the electrode and the stressor include different materials, the memory device may be configured such that the electrode is a layer on the inner surface of the dielectric layer, and the stressor is arranged on an inner surface of the layer of the electrode. Thus, the stressor may be arranged on the inner side of the electrode. For example, a non-conductive material may be used as a stressor on the inner side of the electrode.

The stressor may include at least one of silicon nitride, titanium nitride, silicon oxide, or metal, and such materials may be useful for applying strain.

In the case where the stressor includes a metal, the metal may be at least one of titanium (Ti), ruthenium (Ru), tungsten (W), or molybdenum (Mo).

Alternatively, the metal may be at least one of TiN, SiN, Al, Cr, Sc, Cu, Ni, or Ta.

The stressor may apply the strain to the ferroelectric layer in different ways (e.g., means), e.g., by intrinsic stress and/or thermal stress. Intrinsic stress may arise during the deposition or growth of a material.

Intrinsic stress may be independent of temperature changes or external forces. Intrinsic stress may be caused by factors such as lattice mismatch and/or grain growth and/or crystallite coalescence and/or the incorporation of impurities during layer deposition. A stressor including at least one metal may be an (e.g., efficient) way to utilize intrinsic stress.

Thermal stress may be induced by temperature changes, together with a mismatch of the coefficient of thermal expansion of the materials, that cause differential thermal expansion or contraction of different materials. Thermal stress may be a controllable way to tune the stress of the ferroelectric layer.

Thus, the stressor may have a coefficient of thermal expansion differing from a coefficient of thermal expansion of the ferroelectric layer.

According to a second example embodiment, a method for manufacturing a memory device is provided. The method includes forming a plurality of conductive lines and a plurality of isolating layers, alternately stacked in a vertical direction. The method includes forming a hole extending through the conductive lines and isolating layers, with the hole extending in the vertical direction. The method includes, for each conductive line, forming a dielectric layer including a ferroelectric layer. The dielectric layer is arranged on an inner surface of the hole through the conductive line. The method includes forming an electrode extending through the hole in the vertical direction. The method includes forming a stressor extending through the hole in the vertical direction. For each conductive line, the electrode and the stressor are arranged on an inner side of the dielectric layer, with the electrode in direct contact with an inner surface of the dielectric layer. The electrode and the stressor are formed by conformal deposition.

The hole may be formed by patterning and etching vertically through the plurality of conductive lines and the plurality of isolating layers, e.g., through the stack of conductive lines.

The dielectric layer, or layers, may be deposited on inner sides of the holes. The dielectric layer, or layers, may be deposited by conformal deposition, e.g., by atomic layer deposition (ALD).

The electrode and the stressor may be deposited on the inner side of the dielectric layer. The electrode and stressor may be deposited by conformal deposition, e.g., by atomic layer deposition (ALD). The electrode may be deposited prior to the deposition of the stressor.

Forming the stressor may include depositing a material of the stressor at a temperature below 500 °C. Such a deposition temperature may induce a thermal stress.

A method according to the second example embodiment may have the same or similar improvements, as the improvements described in conjunction with the memory device of the first example embodiment.

### BRIEF DESCRIPTION OF THE FIGURES

The above, as well as additional objects, features, and uses of the present disclosure, may be better understood through the following illustrative and non-limiting detailed description, with reference to the appended drawings. In the drawings, like reference numerals may be used for like elements.

FIG. 1 illustrates a cutaway view of a memory device of an example embodiment of the present disclosure.

FIG. 2 illustrates cutaway view of a memory device of an example embodiment of the present disclosure.

FIG. 3 illustrates a cross-sectional view of a memory device of an example embodiment of the present disclosure.

FIG. 4 illustrates a cross-sectional view of a memory device of an example embodiment of the present disclosure.

FIG. 5A illustrates a vertical cross-sectional view of a memory device of an example embodiment of the present disclosure.

FIG. 5B illustrates a horizontal cross-sectional view of a memory device of an example embodiment of the present disclosure.

FIG. 6 illustrates a cross-sectional view of a memory device of an example embodiment of the present disclosure.

FIG. 7 illustrates a circuit diagram of a memory device of an example embodiment of the present disclosure.

FIG. 8 illustrates a cutaway view of a memory device during production of an example embodiment of the present disclosure.

All the figures are schematic, not necessarily to scale, and generally only show parts which are necessary to elucidate example embodiments, wherein other parts may be omitted or merely suggested.

### DETAILED DESCRIPTION

Example embodiments will now be described more fully hereinafter with reference to the accompanying drawings. That which is encompassed by the claims may, however, be embodied in many different forms and should not be construed as limited to the example embodiments set forth herein; rather, these embodiments are provided by way of example. Furthermore, like numbers refer to the same or similar elements or components throughout.

As shown in the attached drawings, the technical contents and detailed description of the present disclosure are described thereinafter according to example embodiments, which are not to be used to limit the claimed scope. The present disclosure may be embodied in many different forms and may not be construed as limited to the example embodiments set forth herein; rather, the example embodiments are provided for completeness, and to fully convey the scope of the present disclosure.

In the following, axes X, Y, and Z indicate a first horizontal direction, a second horizontal direction transverse to the first horizontal direction, and a vertical direction, respectively. The X-direction and Y-direction are parallel to a main plane of a substrate 2. The Z-direction is parallel to a normal direction to the substrate 2.

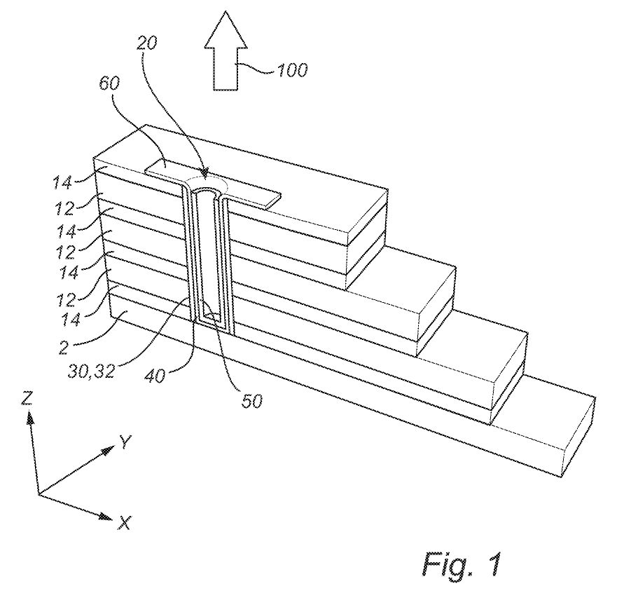

FIG. 1 illustrates a cutaway view of a memory device 1 of an example embodiment of the present disclosure. The memory device 1 includes a plurality of conductive lines 12 and a plurality of isolating layers 14, alternately stacked in a vertical direction 100. In FIG. 1, the vertical direction 100 corresponds to the Z-direction. FIG. 1 shows a (e.g., one) stack of conductive lines. The stack of conductive lines is arranged on a substrate 2.

The memory device 1 includes a hole 20 extending through the conductive lines 12 and the isolating layers 14. The hole 20 extends in the vertical direction 100. For illustration, in FIG. 1, the memory device 1 has been cut along a vertical plane, at the center of the hole 20. The cutaway may be seen as a mirror image of the visible features.

In FIG. 1, a dielectric layer 30 including a ferroelectric layer 32 is arranged on an inner surface of the hole 20. For example, as illustrated in FIG. 1, the dielectric layer 30 comprises a sole ferroelectric layer 32. However, as discussed below, the dielectric layer 30 may include additional dielectric sublayers. For example, the illustrated dielectric layer 30 has a tubular shape (e.g., FIG. 1 shows the tubular shape cut in half, as FIG. 1 is a cutaway view).

In FIG. 1, an electrode 40 extends through the hole 20 in the vertical direction 100. The electrode 40 is arranged on an inner surface of the dielectric layer 30. The illustrated electrode 40 has a tubular shape (e.g., FIG. 1 shows the tubular shape cut in half, as FIG. 1 is a cutaway view).

In FIG. 1, a stressor 50 extends through the hole 20 in the vertical direction 100. The stressor 50 is arranged on an inner surface of the electrode 40. The illustrated stressor 50 has a tubular shape (e.g., FIG. 1 shows the tubular shape cut in half, as FIG. 1 is due to a cutaway view).

Along the vertical direction 100, each intersection between the conductive line 12 and the electrode 40, separated by the dielectric layer 30, may be considered as (e.g., seen as) a capacitor. Thus, for example, the illustrated memory device 1 may be considered to include a stack of three capacitors.

The illustrated conductive lines 12 may be word lines or plate lines.

FIG. 1 further illustrates a bit line 60 connected to the electrode 40. The bit line 60 may be connected to the electrode 40 via a select transistor.

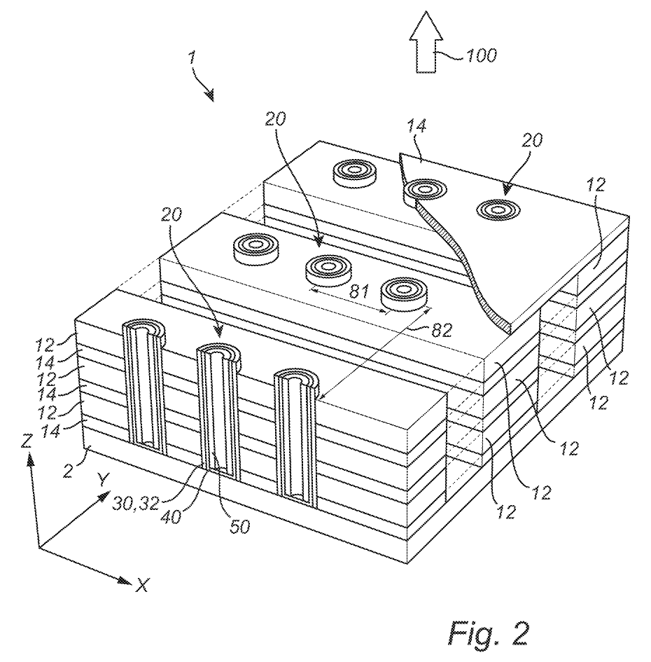

FIG. 2 illustrates a cutaway view of a memory device 1 of an example embodiment of the present disclosure. The memory device 1 includes three stacks of conductive lines 12. Each stack of conductive lines includes three holes 20. The illustrated stacks of conductive lines 12 are arranged on a substrate 2. The holes 20 are spaced apart by a first pitch 81 in the first horizontal direction (X-direction). The holes 20 are spaced apart by a second pitch 82 in the second horizontal direction (Y-direction). Thus, in FIG. 2, the stacks of conductive lines 12 are also spaced apart by a second pitch 82 in the second horizontal direction. In an example embodiment, the first pitch 81 may be below 300 nm or further below 150 nm, and/or the second pitch 82 may be below 300 nm or further below 150 nm. Further, in an example embodiment, the first and second pitches may respectively be in the ranges of 100-120 nm. Such pitches may facilitate synergetic strain effects between the holes in the first and second direction respectively, i.e., that each stressor 50 applies strain to the ferroelectric layers 32 of neighboring holes 20, in addition to applying strain to the ferroelectric layer 32 of its own hole 20. Also, for example, the holes 20 may be arranged in a square lattice, as illustrated in an example embodiment, or in a staggered lattice, or in any other lattice.

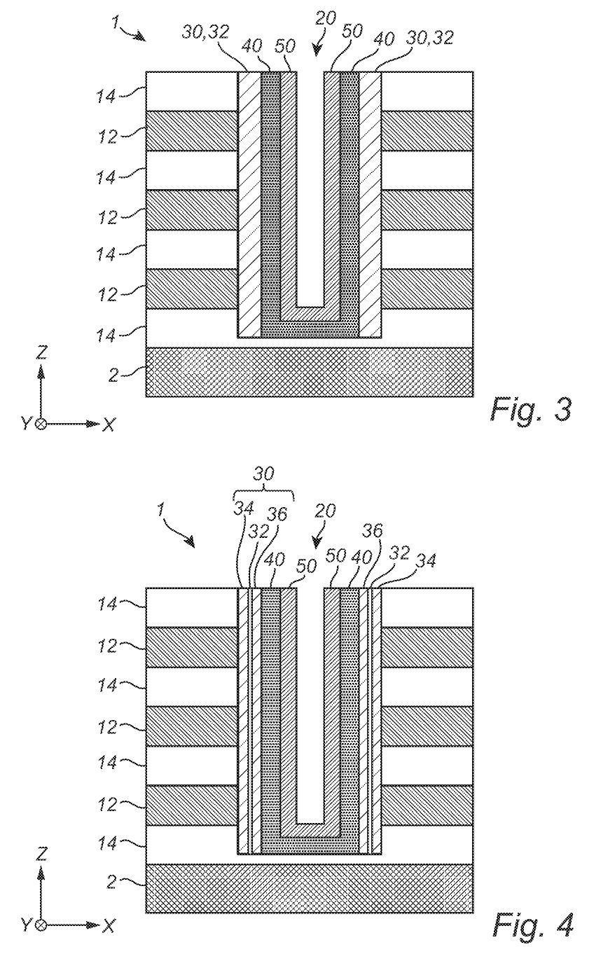

FIG. 3 illustrates a cross-sectional view of a memory device 1 of an example embodiment of the present disclosure, with the cross-section taken in the XZ plane. The illustrated memory device 1 is similar to those of FIGS. 1 and 2 and includes a dielectric layer 30 including a ferroelectric layer 32. As shown, for example, the dielectric layer 30 includes a sole ferroelectric layer 32.

FIG. 4 illustrates a cross-sectional view of a memory device 1 of an example embodiment of the present disclosure, with the cross-section taken in the XZ plane. FIG. 4 illustrates that the dielectric layer 30 may further include layers in addition to the ferroelectric layer 32. In FIG. 4, the dielectric layer 30 includes a first dielectric sublayer 34 between the ferroelectric layer 32 and the conductive line 12 and a second dielectric sublayer 36 between the ferroelectric layer 32 and the electrode 40. In FIG. 4, features and/or components other than the dielectric layer 30 may be arranged in the same or similar way as in FIG. 1.

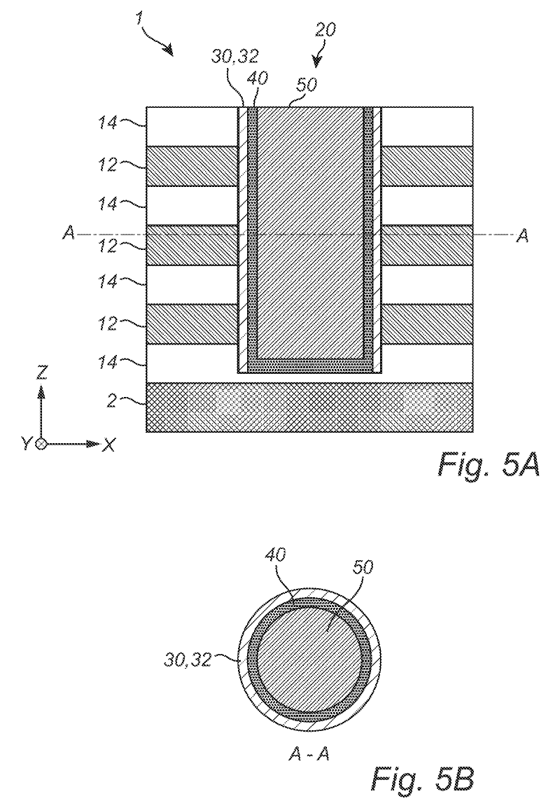

FIG. 5A illustrates a cross-sectional view of a memory device 1 of an example embodiment of the present disclosure, with the cross-section taken in the XZ plane. FIG. 5B illustrates a cross-sectional view of the same memory device 1 of an example embodiment of the present disclosure, with the cross-section taken along a horizontal plane A. The horizontal plane A is indicated in FIG. 5A (in the XY plane). In the illustrated memory device 1, the hole 20 is (e.g., completely) filled by the dielectric layer 30, the electrode 40 and the stressor 50. In the illustrated memory device 1, the hole 20 has a circular cross-section, as seen in FIG. 5B. Further, in FIGS. 5A and 5B, the area of the stressor 50 is larger than the area of the dielectric layer 30. In FIG. 5A, the stressor 50 fills the portion of the hole 20 on the inner side of the electrode 40 completely.

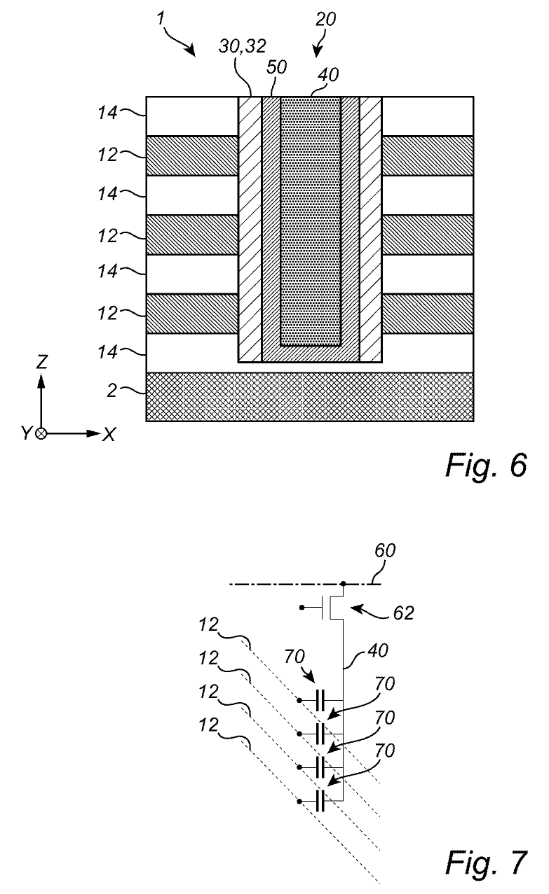

FIG. 6 illustrates a cross-sectional view of a memory device 1 of an example embodiment of the present disclosure, with the cross-section taken in the XZ plane. In the illustrated memory device 1, the hole 20 is (e.g., completely) filled by the dielectric layer 30, the electrode 40 and the stressor 50. FIG. 6 illustrates that the stressor 50 may be a layer, e.g., a tubular layer, between the electrode 40 and the dielectric layer 30. In FIG. 6, for example, the electrode 40 fills the portion of the hole 20 on the inner side of the stressor 50 (e.g., completely).

FIG. 7 illustrates a circuit diagram of a memory device 1 of an example embodiment of the present disclosure. The memory device 1 includes a stack of four conductive lines 12 and an electrode 40. For example, four transistors 70 are illustrated at the intersection between the conductive line 12 and the electrode 40, as formed by the dielectric layer 30. FIG. 7 further shows a bit line 60 and a select transistor 62. and the electrode 40 is connected to the bit line 60 via the select transistor 62.

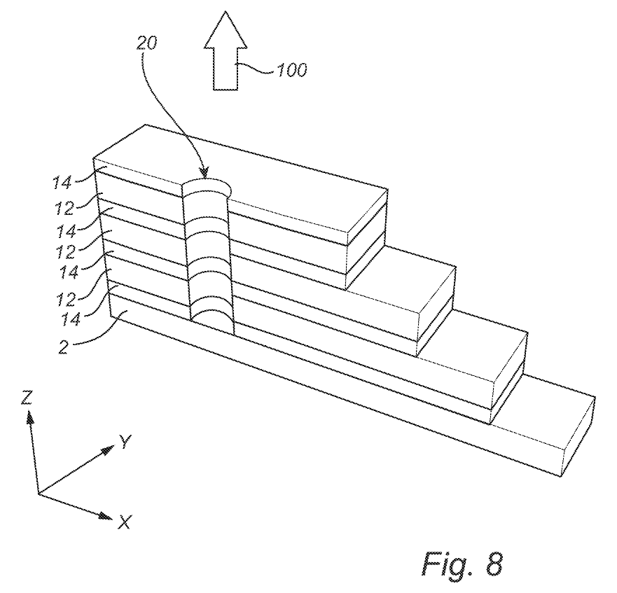

FIG. 8 illustrates a cutaway view of a stack of conductive lines 12 during production of the memory device 1 of an example embodiment of the present disclosure. FIG. 8 may be seen as a step in the production of the memory device 1 of FIG. 1. In FIG. 8, a hole 20 extending through the conductive lines 12 and isolating layers 14 has been formed, e.g., by etching.

The dielectric layer 30, or layers, may (e.g., subsequently) be deposited on inner sides of the hole 20. The dielectric layer 30, or layers, may be deposited by conformal deposition, e.g., by atomic layer deposition (ALD).

The electrode 40 and the stressor 50 may (e.g., subsequently) be deposited on the inner side of the dielectric layer 30. The electrode 40 and the stressor 50 may be deposited by conformal deposition, e.g., by atomic layer deposition (ALD). The electrode 40 may be deposited prior to the deposition of the stressor 50.

In the above, embodiments of the present disclosure have (e.g., mainly) been described with reference to a (e.g., limited) number of examples. However, other examples (e.g., than the ones disclosed above) are (e.g., equally) possible within the scope of the present disclosure, as provided by the appended claims.

While some embodiments have been illustrated and described in detail in the appended drawings and the foregoing description, such illustration and description are to be considered illustrative and not restrictive. Other variations to the disclosed embodiments can be understood and effected in practicing the claims, from a study of the drawings, the disclosure, and the appended claims. The mere fact that certain measures or features are recited in mutually different dependent claims does not indicate that a combination of these measures or features cannot be used. Any reference signs in the claims should not be construed as limiting the scope.

What is claimed is:

1. A memory device comprising: a plurality of conductive lines and a plurality of isolating layers, wherein the plurality of conductive lines and the plurality of isolating layers are alternately stacked in a vertical direction;

2. The memory device of claim 1 wherein, for each conductive line, a magnitude of the strain of the ferroelectric layer is at least 0.03%.new claim...

3. The memory device of claim 1 wherein, for each conductive line, the strain of the ferroelectric layer is compressive strain.

4. The memory device of claim 1, wherein the stressor applies the strain via intrinsic stress or thermal stress.

5. The memory device of claim 1, wherein, for each conductive line, the hole through the conductive line is filled by the dielectric layer, the electrode and the stressor.

6. The memory device of claim 1, wherein, for each conductive line, an area of the stressor is larger than an area of the dielectric layer.

7. The memory device of claim 1, wherein the hole has a circular cross-section.

8. The memory device of claim 1, wherein the electrode comprises a first material and the stressor comprises a second material, wherein the first material and the second material are the same material.

9. The memory device of claim 1, wherein the electrode comprises a first material and the stressor comprises a second material, wherein the first material is different than the second material, and wherein the electrode is a layer on an inner surface of the dielectric layer, and wherein the stressor is arranged on an inner surface of the layer of the electrode.

10. The memory device of claim 1, wherein the plurality of conductive lines are word lines or plate lines.

11. The memory device of claim 1, wherein the stressor is arranged on an inner surface of the electrode or between the electrode and the dielectric layer.

12. The memory device of claim 1, wherein the ferroelectric layer comprises hafnium oxide, lead zirconate titanate, strontium bismuth tantalate, barium strontium titanate, or perovskite ferroelectrics.

13. The memory device of claim 1, wherein the stressor comprises silicon nitride, titanium nitride, silicon oxide, or metal.

14. The memory device of claim 13, wherein the stressor comprises a metal, wherein the metal is titanium, ruthenium, tungsten, or molybdenum.

15. The memory device of claim 1, wherein the electrode comprises tungsten, molybdenum, ruthenium, copper, titanium, doped polysilicon, or titanium nitride.

16. The memory device of claim 1, wherein the dielectric layer further comprises a dielectric sublayer between the ferroelectric layer and each conductive line.

17. The memory device of claim 1, wherein the stressor has a first coefficient of thermal expansion and the ferroelectric layer has a second coefficient of thermal expansion, wherein the first coefficient of thermal expansion is different than the second coefficient of thermal expansion.

18. The memory device of claim 1, further comprising a bit line and a select transistor, wherein the electrode is connected to the bit line via the select transistor.

19. A method for manufacturing a memory device, the method comprising: forming a plurality of conductive lines and a plurality of isolating layers, wherein the plurality of conductive lines and the plurality of isolating layers are alternately stacked in a vertical direction; forming a hole extending through the plurality of conductive lines and the plurality of isolating layers, wherein the hole extends in the vertical direction; for each conductive line, forming a dielectric layer comprising a ferroelectric layer, wherein the dielectric layer is arranged on an inner surface of the hole through each conductive line; forming an electrode extending through the hole in the vertical direction; and forming a stressor extending through the hole in the vertical direction, wherein, for each conductive line, the electrode and the stressor are arranged on an inner side of the dielectric layer, wherein the electrode is in direct contact with an inner surface of the dielectric layer, and wherein the electrode and the stressor are formed by conformal deposition.

20. The method of claim 19, wherein forming the stressor comprises depositing a material of the stressor at a temperature below 500 °C.
